(19) United States
(12) Patent Application Publication
(10) Pub. No.: US 2005/0133934 A1
(43) Pub. Date: Jun. 23, 2005

(54) Thermal interface material bonding

(76) Inventors: James P. Mellody, Phoenix, AZ (US); Sabina J. Houle, Phoenix, AZ (US); Carl L. Deppisch, Phoenix, AZ (US); Joni G. Hansen, Phoenix, AZ (US); Marvin J. Burgess, Naperville, IL (US); Robert C. DeBlieck, Cary, IL (US)

Correspondence Address: Buckley, Maschoff & Talwalkar LLC, Five Elm Street, New Canaan, CT, 06840, US

(21) Appl. No.: 10/744,583

(22) Filed: Dec. 23, 2003

(51) Int. Cl. H01L 21/44; H01L 23/48

(52) U.S. Cl. 257/779; 438/612; 257/778; 438/108; 257/712

(57) ABSTRACT

A system may include placement of a first surface of a solder preform on a first surface of a heat dissipator, and rolling of a roller across a second surface of the solder preform. In some embodiments, the system further includes pressing the solder preform and the heat dissipator against each other.

### BACKGROUND

An integrated circuit (IC) die includes a semiconductor substrate and various electronic devices integrated therewith. The electronic devices may generate heat during operation of the IC die. This heat may adversely affect the performance of the IC die, and in some cases may damage one or more of its integrated electronic devices.

Conventional systems use fans and/or temperature monitors to regulate the heat to which an IC die is subjected. Heat dissipators (e.g. heat spreaders, heat sinks, and/or heat pipes) may also be used to direct heat away from an IC die. A thermal interface material may be disposed between a heat dissipator and an IC die in order to bond the heat dissipator to the IC die and/or to assist the transmission of heat from the IC die to the heat dissipator.

### BRIEF DESCRIPTION OF THE DRAWINGS

FIG. 1 is a perspective view of an apparatus according to some embodiments.

FIG. 2 is a diagram of a process according to some embodiments.

FIG. 3 is a cross-sectional side view of a heat dissipator according to some embodiments.

FIG. 4 is a cross-sectional side view of a heat dissipator and a solder preform according to some embodiments.

FIGS. 5A through 5C are cross-sectional side views of a heat dissipator, a solder preform, and a roller according to some embodiments.

FIG. 6 is a diagram of a process according to some embodiments.

FIGS. 7A and 7B illustrate systems to remove oxides according to some embodiments.

FIGS. 8A and 8B are cross-sectional side views of a heat dissipator, a solder preform, and a press according to some embodiments.

FIG. 9A is a cross-sectional side view of a heat dissipator, a solder preform, a press, a heating device, and a heat control according to some embodiments.

FIG. 9B is a cross-sectional side view of a heat dissipator, a solder preform, a press, a heating device, and a heat control according to some embodiments.

FIG. 9C is a cross-sectional side view of a heat dissipator, a solder preform, a press, a vibration device, and a vibration control according to some embodiments.

FIGS. 10A and 10B are side views of a heat dissipator, a solder preform, a form, an evacuator, and a dispenser according to some embodiments.

FIG. 11 is a side view of a system according to some embodiments.

### DETAILED DESCRIPTION

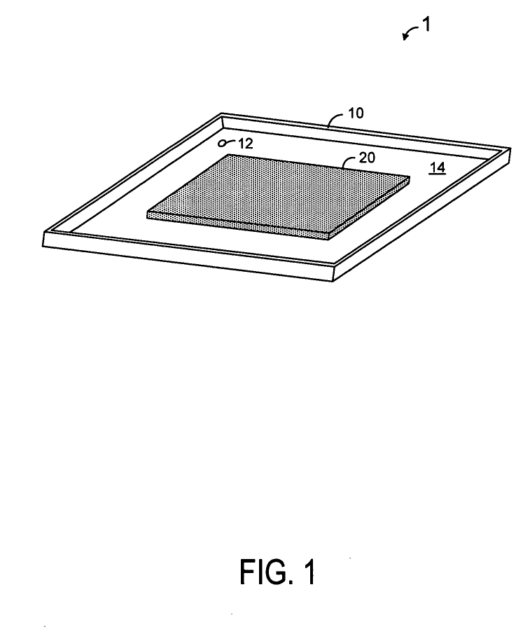

FIG. 1 is a perspective view of apparatus 1 according to some embodiments. Apparatus 1 comprises heat dissipator 10 and solder preform 20. Apparatus 1 may be used to dissipate heat from an IC die according to some embodiments. Accordingly, heat dissipator 10 may define vent hole 12 to assist in gas, moisture and/or heat dissipation from the IC die.

As shown, heat dissipator 10 comprises an integrated heat spreader. Heat dissipator 10 may comprise any other structure for dissipating heat according to some embodiments, including but not limited to a heat pipe and a heat sink. Heat dissipator 10 may comprise any currently- or hereafter-known thermally conductive material. Non-exhaustive examples include copper and aluminum, which may or may not be plated with a different thermally-conductive material, including but not limited to nickel and gold. In some embodiments, heat dissipator 10 comprises nickel-plated copper that is in turn plated with gold, silver, tin, palladium, and/or another material.

Solder preform 20 may also comprise any suitable solder preform. In some embodiments, solder preform 20 is composed of elemental indium solder, indium-based solder, tin-based solder, or another type of soft solder.

A first surface of solder preform 20 is coupled to first surface 14 of heat dissipator 10. According to some embodiments, solder preform 20 is coupled to first surface 14 by placing the first surface of solder preform 20 on first surface 14 and by rolling a roller across second surface 22 of solder preform 20. Such coupling may produce a substantially voidless interface between solder preform 20 and heat dissipator 10 in some embodiments. In comparison to other interfaces, a voidless interface may provide increased strength at the interface, increased heat transfer across the interface and/or increased resistance to the development and propagation of cracks at the interface.

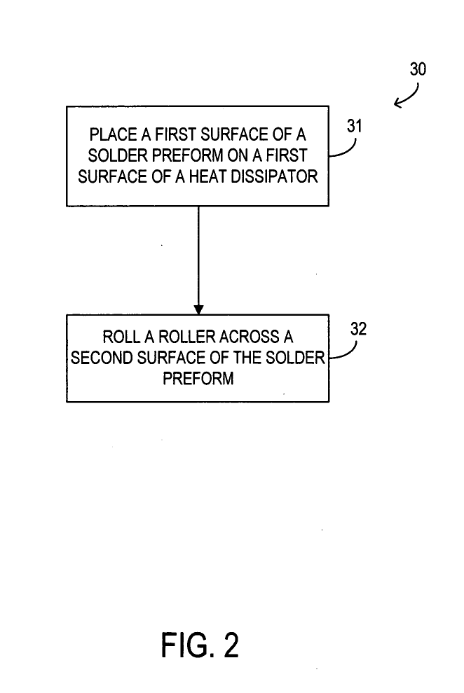

FIG. 2 is a diagram of process 30 to fabricate apparatus 1 according to some embodiments. Process 30 may be executed by one or more devices, and all or a part of process 30 may be executed manually. Process 30 may be executed by an entity different from an entity that manufactures heat dissipator 10 and/or solder preform 20.

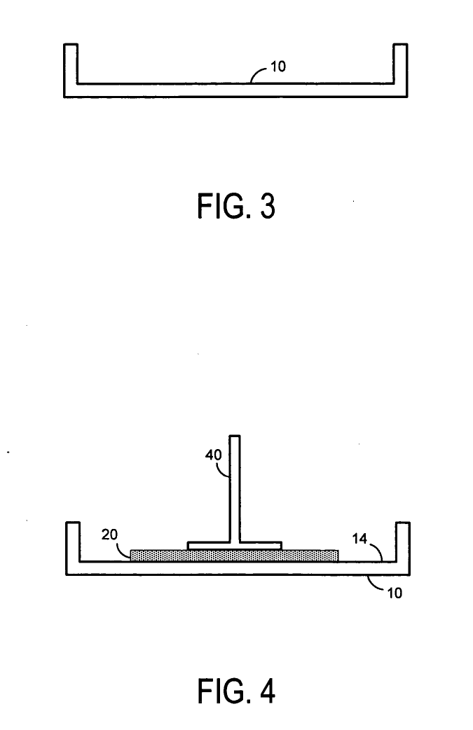

Initially, at 31, a first surface of a solder preform is placed on a first surface of a heat dissipator. FIG. 3 is a cross-sectional side view of heat dissipator 10 for purposes of explaining some embodiments. Heat dissipator 10 may rest on any suitable surface prior to process 30.

FIG. 4 illustrates placement of solder preform 20 at 31 according to some embodiments. Generally, pick and place device 40 picks solder preform 20 from a repository such as a tape reel or a stack using suction devices, clamping devices and/or adhesives, transports solder preform 20 to a position above heat dissipator 10, places a first surface of solder preform 20 at an appropriate position on first surface 14 of heat dissipator 10, and releases solder preform 20. Pick and place device 40 thereafter moves out of the region above solder preform 20. Any currently- or hereafter-known placement systems may be used at 31.

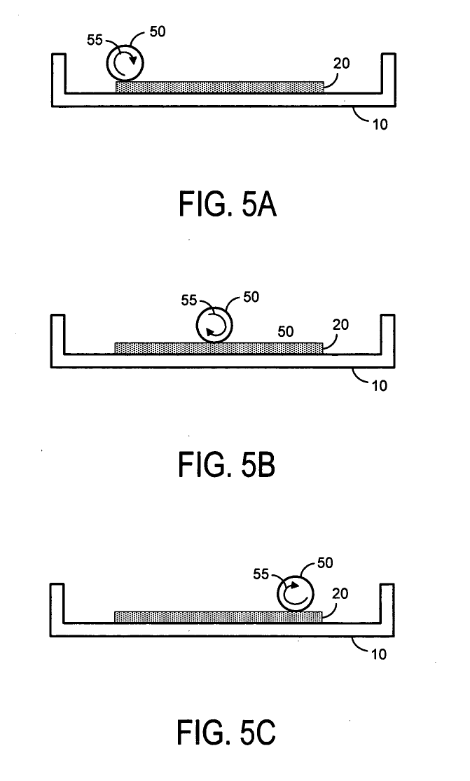

Next, at 32, a roller is rolled across a second surface of solder preform 20. FIGS. 5A through 5C illustrate roller 50 rolling across second surface 22 according to some embodiments. Arrow 55 indicates the direction of rotation of roller 50. Roller 50 may comprise a teflon-plated steel roller with a 0.1875 inch diameter. According to some embodiments, roller 50 applies 20 pounds of force to solder preform 20. Other suitable roller materials, roller sizes, and pressures may be used at 32 in some embodiments.

According to some embodiments, roller 50 rolls across second surface 22 two or more times at 32. Roller 50 may roll back and forth between the position shown in FIG. 5C and the position shown in FIG. 5A. Roller 50 may roll across two or more axes of second surface 22 in some embodiments.

Some embodiments of process 30 include dispensing a substantially inert gas (e.g. nitrogen, argon) into a volume surrounding preform 20 at 31 and/or at 32. The gas may prevent the build-up of oxides on preform 20 and/or on heat dissipator 10.

Process 30 may create a mechanical bond between solder preform 20 and heat dissipator 10. Moreover, a resulting interface between solder preform 20 and heat dissipator 10 may be substantially voidless in some embodiments. Process 30 may also or alternatively cause plastic deformation of solder preform 20, which may assist in breaking up surface oxides located on solder preform 20.

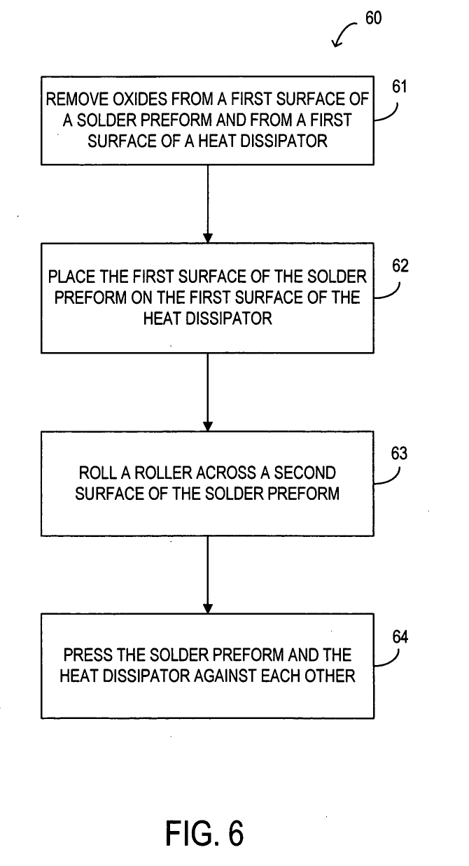

FIG. 6 is a diagram of process 60 to fabricate apparatus 1 according to some embodiments. Process 60 may be executed by one or more devices, and all or a part of process 30 may be executed manually. Process 60 may be executed by an entity different from an entity that manufactures heat dissipator 10 and/or solder preform 20.

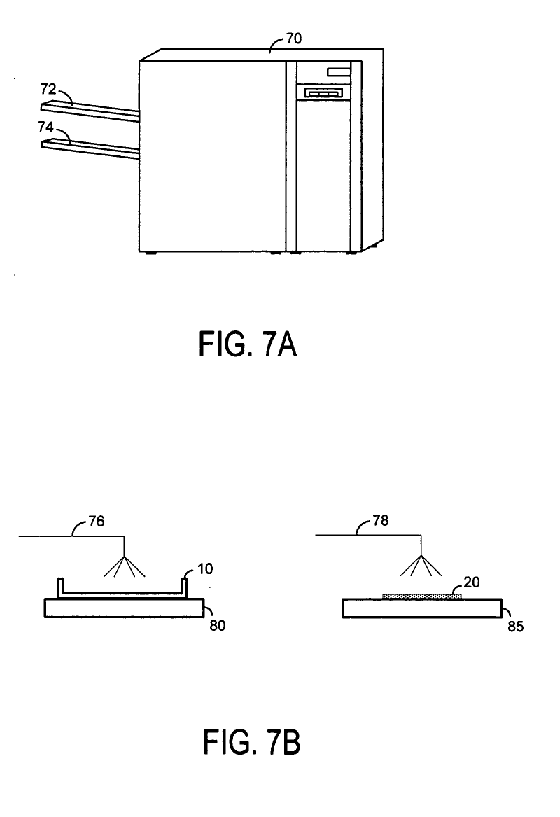

Oxides are removed from a first surface of a solder preform and from a first surface of a heat dissipator at 61. Removal of the oxides may increase interatomic diffusion and promote the later formation of a substantially voidless interface between the two surfaces. FIG. 7 illustrates plasma etcher 70 for removing the oxides at 61 according to some embodiments. Plasma etcher 70 may be a dedicated unit in which one or more solder preforms and/or heat dissipators and received by input tray 72, etched using a plasma (e.g. hydrogen plasma), and output to output tray 74. Any currently- or hereafter-known system or systems for plasma etching made by used in conjunction with some embodiments.

FIG. 7B illustrates a system for removing oxides at 61 according to some embodiments. Shown are acid applicator 76 and acid applicator 78 for applying acid to a first surface of heat dissipator 10 and to a first surface of solder preform 20, respectively. Also shown are supports 80 and 85 respectively supporting heat dissipator 10 and solder preform 20.

In operation, acid applicator 76 may apply acid to the first surface of heat dissipator 10 and, after a suitable time period has passed, may rinse the acid off of the first surface using deionized and/or distilled water. Acid applicator 78 may similarly apply acid to the first surface of solder preform 20 and, after a suitable time period, may rinse the acid off of the first surface using deionized and/or distilled water. According to some embodiments, acid is dispensed onto both heat dissipator 10 and solder preform 20 by applicator 76, simultaneously or at different times, and is rinsed off of both heat dissipator 10 and solder preform 20 by applicator 78, also simultaneously or at different times.

The acid used in some embodiments may comprise hydrochloric and/or sulfuric acid, and may preferentially attack oxides of the material to which it is to be applied. Any other suitable acid application system may be employed at 61, including an acid dip arrangement.

Next, at 62, the first surface of the solder preform is placed on the first surface of the heat dissipator as described with respect to 31 of process 30. Similarly, a roller may be rolled across a second surface of the solder preform at 63 as described with respect to 32 of process 30. The solder preform and the heat dissipator are then pressed against each other at 64. In some embodiments, this pressure may promote interatomic diffusion between the two surfaces.

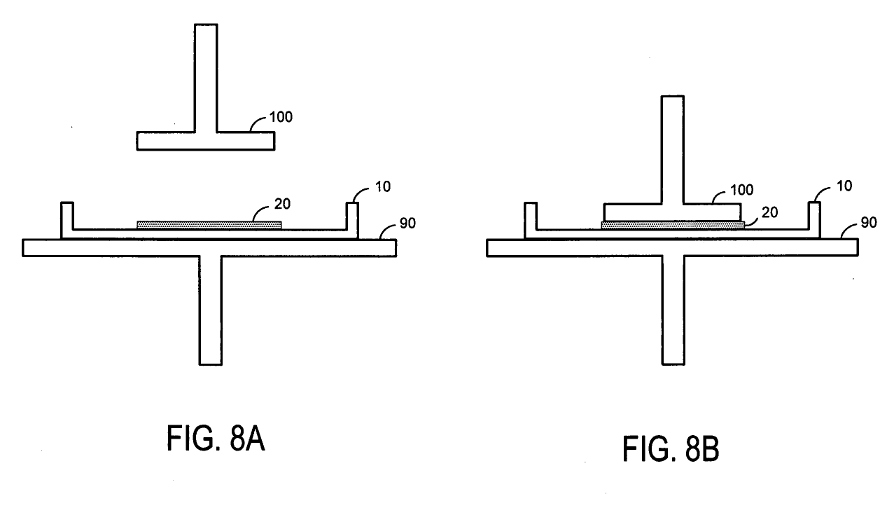

FIGS. 8A and 8B illustrate the pressing of solder preform 20 and heat dissipator 10 against each other according to some embodiments. FIG. 8B shows a press comprising platen 90 and ram 100. A second surface of heat dissipator 10 rests on platen 90 and ram 100 is positioned above solder preform 20. Platen 90 and ram 100 are configured for relative movement toward one another. That is, platen 90 may move toward stationary ram 100, ram 100 may move toward stationary platen 90, and/or platen 90 and ram 100 may both move toward each other.

In some embodiments, ram 100 contacts a second surface of solder preform 20 at 64. FIG. 8B shows platen 90 and ram 100 pressing solder preform 20 and heat dissipator 10 against each other. Such pressure may cause solder preform 20 and/or heat dissipator 10 to deform.

According to some embodiments, a substantially inert gas (e.g. nitrogen, argon) is dispensed into a volume surrounding preform 20 at 63 and/or at 64. The gas may prevent the build-up of oxides on preform 20 and/or on heat dissipator 10.

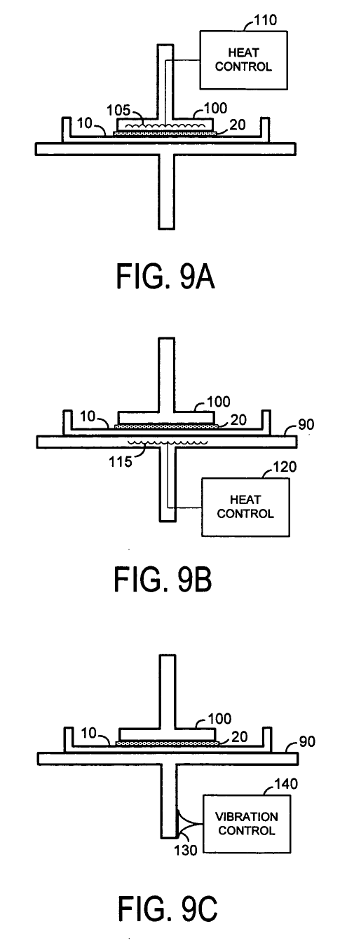

FIGS. 9A through 9C illustrate systems for applying energy to the preform/dissipator interface while preform 20 and dissipator 10 are pressed against each other at 64. FIG. 9A shows heating element 105 disposed within ram 100 and heat control 110 coupled to heating element 105. Heat control 110 may control an amount of heat that is generated by heating element 105 and transferred to an interface of preform 20 and dissipator 10 at 64.

Heating element 115 may be disposed within platen 90 and coupled to heat control 120 as shown in FIG. 9B. As described with respect to heat control 110, heat control 120 may control an amount of heat that is generated by heating element 115 and transferred to the interface of preform 20 and dissipator 10 at 64. Heating the interface may assist the diffusion of solder preform 20 into heat dissipator 10 by softening the material thereof. Some embodiments may comprise each of heating element 105, heat control 110, heating element 115, and heat control 120.

FIG. 9C shows horn 130 coupled to platen 90 and to vibration control 140. Horn 130 may comprise a vibration device to apply vibratory energy to platen 90 at 64. In some embodiments, horn 130 is coupled to ram 100. The vibratory energy may comprise ultrasonic and/or mechanical vibration. Vibration control 140 may control a frequency and/or amplitude of the vibratory energy applied by horn 130. Vibratory energy may assist in plastically deforming and breaking up surface oxides on the mating surfaces of solder preform 20 and heat dissipator 10.

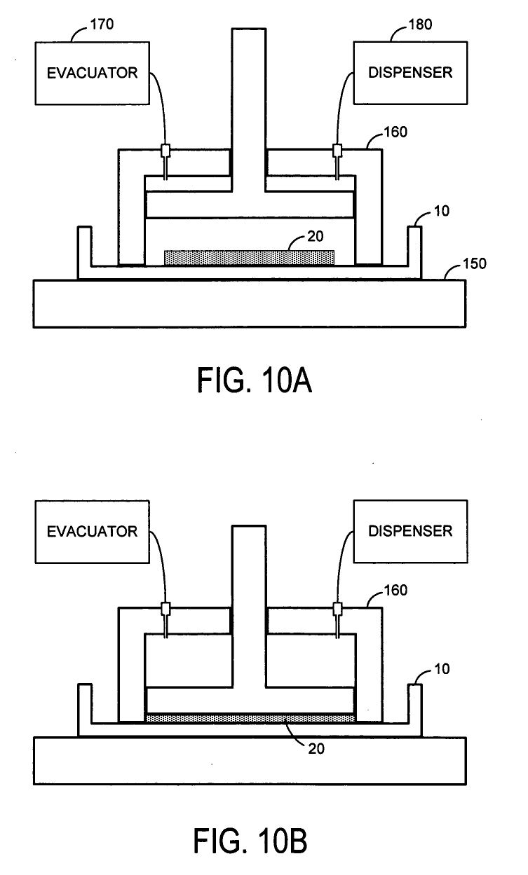

FIGS. 10A and 10B illustrate the pressing of solder preform 20 and heat dissipator 10 against each other according to some embodiments. Specifically, FIG. 10A shows heat dissipator 10 resting on base 150, which may comprise platen 90 according to any of the above-described embodiments or another suitable support surface. A first surface of solder preform 20 has been placed on a first surface of heat dissipator 10. Also placed on heat dissipator 10 and around a perimeter of solder preform 20 is form 160. Form 160 may comprise any suitable material, including teflon-plated steel.

Prior to 64, evacuator 170 may operate to evacuate air from a volume surrounding solder preform 20 and surrounded by form 160. In some embodiments, dispenser 180 also or alternatively operates prior to 64 to dispense an inert gas (e.g. nitrogen, argon) into the volume. Ram 100 is then moved downward to press solder preform 20 against heat dissipator 10.

FIG. 10B shows ram 100 after having pressed solder preform 20 against heat dissipator 10 in some embodiments of 64. Solder preform 20 has become thinner than shown in FIG. 10A and extends to the walls of form 160. Form 160 may thereby allow precise control over the final dimensions of solder preform 160 and may allow the use of greater pressure at 64 than otherwise usable.

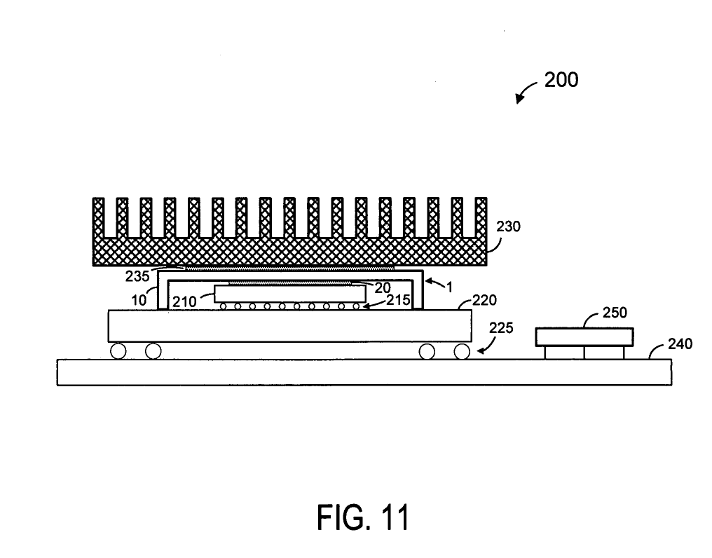

FIG. 11 illustrates a system according to some embodiments. System 200 includes IC die 210 coupled to solder preform 20 of apparatus 1. IC die 210 includes integrated electrical devices and may be fabricated using any suitable material and fabrication techniques. In some embodiments, IC die 210 comprises a microprocessor chip having a silicon substrate.

Electrical contacts 215 are coupled to IC die 210 and may comprise Controlled Collapse Chip Connect (C4) solder bumps. Electrical contacts 215 may be electrically coupled to the electrical devices that are integrated into IC die 210. The electrical devices may reside between a substrate of IC die 210 and electrical contacts 215 in a “flip-chip” arrangement. In some embodiments, such a substrate resides between the electrical devices and electrical contacts 215.

Electrical contacts 215 are also coupled to electrical contacts (not shown) of substrate 220. In some embodiments, die 210 is electrically coupled to substrate 220 via wirebonds in addition to or as an alternative to electrical contacts 215. Substrate 220 may comprise any ceramic, organic, and/or other suitable material, and includes solder balls 225 for carrying power and I/O signals between IC die 210 and external devices. Alternative interconnects such as through-hole pins may be used instead of solder balls.

Heat dissipator 10 is coupled to heat sink 230. As such, apparatus 1 may increase a thermal coupling between die 210 and heat sink 230. Heat sink 230 may comprise any currently- or hereafter-known passive or active heat sink. Heat sink 230 is coupled to heat dissipator 10 by solder preform 235. Solder preform 235 may be coupled to heat dissipator 10 using process 30 and/or process 60 described above. Process 30 and/or process 60 may be used to couple a solder preform to any structure to which solder may be bonded, including but not limited to metallized structures.

Motherboard 240 may electrically couple memory 250 to IC die 210. More particularly, motherboard 240 may comprise a memory bus (not shown) that is electrically coupled to solder balls 225 and to memory 250. Memory 250 may comprise any type of memory for storing data, such as a Single Data Rate Random Access Memory, a Double Data Rate Random Access Memory, or a Programmable Read Only Memory.

The several embodiments described herein are solely for the purpose of illustration. Some embodiments may include any currently or hereafter-known versions of the elements described herein. Therefore, persons skilled in the art will recognize from this description that other embodiments may be practiced with various modifications and alterations.

1. A method comprising:
placing a first surface of a solder preform on a first surface of a heat dissipator; and
rolling a roller across a second surface of the solder preform.

2. A method according to claim 1, further comprising:
pressing the solder preform and the heat dissipator against each other.

3. A method according to claim 2, the pressing step comprising:
pressing a ram against the solder preform; and
heating the ram to heat the solder preform.

4. A method according to claim 2, wherein the heat dissipator rests on a platen during the pressing step, and wherein the pressing step comprises:
heating the platen to heat the heat dissipator.

5. A method according to claim 4, the pressing step further comprising:
applying vibratory energy to the platen.

6. A method according to claim 2, further comprising:
evacuating air from a volume surrounding the solder preform prior to the pressing step.

7. A method according to claim 2, further comprising:
placing a form on the heat dissipator and around a perimeter of the preform prior to the pressing step.

8. A method according to claim 7, further comprising:
evacuating air from a volume surrounding the solder preform after placing the form and prior to the pressing step.

9. A method according to claim 7, further comprising:
dispensing a substantially inert gas into a volume surrounding the solder preform after placing the form and prior to the pressing step.

10. A method according to claim 2, further comprising:
dispensing a substantially inert gas into a volume surrounding the solder preform prior to the pressing step.

11. A method according to claim 1, further comprising:
removing oxides from the first surface of the solder preform and the first surface of the heat dissipator prior to the placing step.

12. A method according to claim 11, wherein removing oxides comprises:
plasma etching the first surface of the solder preform and the first surface of the heat dissipator.

13. A method according to claim 11, wherein removing oxides comprises:
applying acid to the first surface of the solder preform and to the first surface of the heat dissipator; and
rinsing the first surface of the solder preform and the first surface of the heat dissipator with water to remove the acid.

14. A method according to claim 1, further comprising:
dispensing a substantially inert gas into a volume surrounding the solder preform prior to the rolling step.

15. A method according to claim 1, wherein the heat dissipator comprises:
copper and/or aluminum plated with nickel, gold, silver, tin, and/or palladium.

16. A method according to claim 1, wherein the solder preform comprises:
elemental indium solder, tin-based solder and/or indium-based solder.

17. A system comprising:
a placement device to place a first surface of a solder preform on a first surface of a heat dissipator; and
a roller to roll across a second surface of the solder preform.

18. A system according to claim 17, further comprising:
a press to press the solder preform and the heat dissipator against each other.

19. A system according to claim 18, the press comprising:
a platen to contact a second surface of the heat dissipator; and
a ram to contact the second surface of the solder preform.

20. A system according to claim 19, the ram comprising:
a heating element to heat the solder preform.

21. A system according to claim 19, the platen comprising:
a heating element to heat the heat dissipator.

22. A system according to claim 18, further comprising:
a vibration device to apply vibratory energy to the press.

23. A system according to claim 18, further comprising:
an evacuator to evacuate air from a volume surrounding the solder preform prior to pressing the solder preform and the heat dissipator against each other.

24. A system according to claim 18, further comprising:
a form to place on the first surface of the heat dissipator and around a perimeter of the preform prior to pressing the solder preform and the heat dissipator against each other.

25. A system according to claim 24, further comprising:
an evacuator to evacuate air from a volume surrounding the solder preform after placing the form and prior to pressing the solder preform and the heat dissipator against each other.

26. A system according to claim 24, further comprising:
a dispenser to dispense a substantially inert gas into a volume surrounding the solder preform after placing the form and prior to pressing the solder preform and the heat dissipator against each other.

27. A system according to claim 18, further comprising:
a dispenser to dispense a substantially inert gas into a volume surrounding the solder preform prior to pressing the solder preform and the heat dissipator against each other.

28. A system according to claim 17, further comprising:
an oxide remover to remove oxides from the first surface of the solder preform and the first surface of the heat dissipator prior to placing the first surface of the solder preform on the first surface of the heat dissipator.

29. A system according to claim 28, wherein the oxide remover comprises:
a plasma etcher to plasma etch the first surface of the solder preform and the first surface of the heat dissipator.

30. A system according to claim 28, wherein the oxide remover comprises:
an acid applicator to apply acid to the first surface of the solder preform and to the first surface of the heat dissipator, and to rinse the first surface of the solder preform and the first surface of the heat dissipator with water to remove the acid.

31. A system according to claim 17, further comprising:
a dispenser to dispense a substantially inert gas into a volume surrounding the solder preform prior to rolling the roller across the second surface.

32. A system according to claim 17, wherein the heat dissipator comprises:
copper and/or aluminum plated with nickel, gold, silver, tin, and/or palladium.

33. A system according to claim 17, wherein the solder preform comprises:
elemental indium solder, tin-based solder and/or indium-based solder.

34. A system comprising:
a microprocessor comprising:
a heat dissipator;
a solder preform coupled to the heat dissipator by a roller; and
an integrated circuit die coupled to the solder preform; and
a double data rate memory electrically coupled to the integrated circuit die.

35. A system according to claim 34, further comprising:
a motherboard electrically coupled to the integrated circuit die and to the memory.

36. A system according to claim 34, the microprocessor further comprising:
a heat sink coupled to the heat dissipator.

37. A system according to claim 34, wherein the heat dissipator comprises:
copper and/or aluminum plated with nickel, gold, silver, tin, and/or palladium.

38. A system according to claim 34, wherein the solder preform comprises:
elemental indium solder, tin-based solder and/or indium-based solder.
